(19) United States
(12) Patent Application Publication
(10) Pub. No.: US 2009/0229655 A1
(43) Pub. Date: Sep. 17, 2009

(54) Solar Cell

(76) Inventor: Chen-Sheng Lee, Lu Chu Shiang (TW)

Correspondence Address: KAMRATH & ASSOCIATES P.A., 4825 OLSON MEMORIAL HIGHWAY, SUITE 245, GOLDEN VALLEY, MN, 55422, US

(21) Appl. No.: 12/047,383

(22) Filed: Mar. 13, 2008

(51) Int. Cl. H01L 31/048

(52) U.S. Cl. 136/251

(57) ABSTRACT

A solar cell is provided. The solar cell defines a receiving room in where at least a cell unit is located. A transparent cover plate is placed over the cell unit. In addition, the transparent cover plate includes a base plate and a structured plate which are adhered to each other. Wherein, the base plate is made from inflexible material and the structured plate is made from a photo resin. Moreover, there are pluralities of convex first patterns disposed on the incident surface of the structured plate.

### BACKGROUND OF THE INVENTION

1. Field of the Invention

The present invention relates to a solar cell. More particularly, the present invention relates to a solar cell with a transparent cover plate which includes a base plate and a structured plate.

2. Description of the Prior Art

In the recent years, the greenhouse effect caused by the mass generation of greenhouse gas and the price upswing of petroleum result in the fact that people are giving more and more weight to the renewable energy. In the present, the renewable energy includes: solar energy, wind power, geothermal energy, hydro power, tide energy, ocean thermal energy conversion and biomass energy, wherein the solar energy is the most generally used among the renewable energy.

Please refer to FIG. 1 for a prior solar cell. The solar cell 10 defines a receiving room 14, which includes an encapsulant material 17 and pluralities of polysilicon solar cells 16. The polysilicon solar cells 16 are connected in series by wire 18, and the encapsulant material 17 is ethylene-vinyl acetate copolymer for example. A glass cover plate 12 is placed over the solar cell 10. The sun light can transmit the glass cover plate 12, irradiating the polysilicon solar cells 16. However, when the angle of incident sun light to the normal of the incident surface 121 of the glass cover plate 12 is greater than the critical angle, the total reflection occurs, which means the sun light will stop crossing the glass cover plate 12, with the result that the efficiency of the solar cell 10 decreases.

Therefore, some prior articles disclosed patterns disposed on the incident surface of the glass cover plate to prevent total reflection. For example, some concave patterns are formed on the incident surface to prevent total reflection. However, the concave patterns are apt to accumulate dust and/or water, especially in the desert. Therefore, the glass cover plate needs cleaning frequently, increasing the cost of maintenance. Moreover, the concave patterns are formed on fused glass in the industry. As the glass cools down, the patterns thereof shrink due to the larger expansion coefficient of glass, with the result that the dimensions of patterns are often undesirable.

It would, therefore, be desirable to prevent the incident surface of glass cover plate from accumulating dust and water more effectively and to form patterns on the incident surface more precisely.

### SUMMARY OF THE INVENTION

The present invention provides a solar cell, wherein the incident surface of a transparent cover plate thereof can present the accumulation of dust and/or water more effectively, and patterns on the incident surface can be more precisely formed.

To achieve the foregoing and other subjects, the invention provides a solar cell. The solar cell defines a receiving room in where at least a cell unit is located. A transparent cover plate is placed over the cell unit. The solar cell is further characterized in that: the transparent cover plate includes a base plate and a structured plate which are adhered to each other, wherein the base plate is made from inflexible material, the structured plate is made from a photo resin and pluralities of convex first patterns are disposed on the incident surface of the structured plate.

In the present solar cell, a transparent waterproof material is spread over the incident surface of the structured plate.

In the present solar cell, the waterproof material is polytetrafluoro ethylene.

In the present solar cell, the first patterns are bar-shaped, and the sections thereof are triangular for example. Wherein, the height is half the width. Or, the sections of the first patterns are arc-shaped, for example. Wherein, the height and the width can be related by the following formula:

Height/Width=0.05˜0.25

In the present solar cell, there are arc-shaped grooves between the first patterns.

In the present solar cell, the base is made from glass. Moreover, if the cell unit is a singlesilicon solar cell, the thickness of the base plate is between 3 mm to 12 mm.

Due to the convex first patterns disposed on the transparent cover plate, the transparent cover plate can prevent the accumulation of dust and water more effectively. Moreover, the structured plate is made from a photo resin, which shrinks slightly during curing. Therefore, the precision of the dimensions of the first patterns is more easily controlled and the transparent cover plate can reach the requirement for the optic effect as well.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a prior solar cell.

FIG. 2A is a solar cell of the first embodiment;

FIG. 2B is an arc-shaped groove.

FIG. 3A to FIG. 3D shows a manufacturing process of a transparent cover plate of the first embodiment.

FIG. 4 is a comparative drawing, which shows luminous flux of transparent cover plates of the first embodiment and a comparative embodiment when the incident angle of light varies.

FIG. 5 is a transparent cover plate of the solar cell of the second embodiment.

FIG. 6 is a top view of a transparent cover plate of a solar cell of the third embodiment.

FIG. 7 is a transparent cover plate of the solar cell of the fourth embodiment.

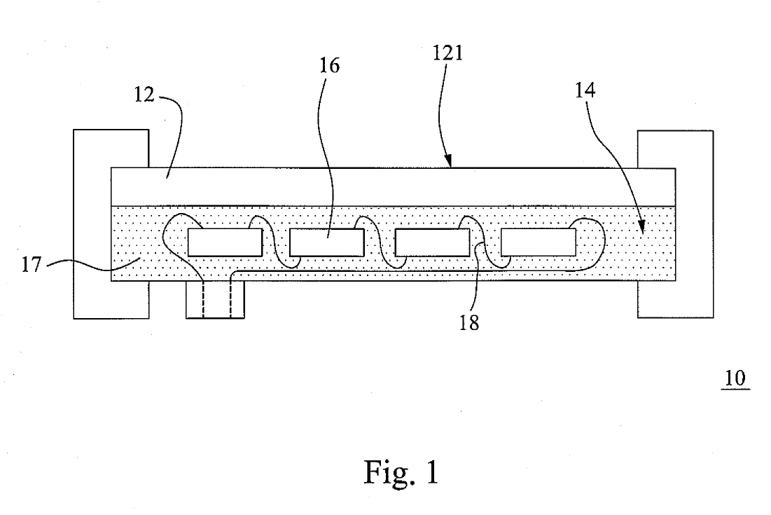

### DESCRIPTION OF THE PREFERRED EMBODIMENTS

Reference will now be made in detail to the preferred embodiments of the present invention, examples of which are illustrated in the accompanying drawings. Wherever possible, the same reference numbers are used in the drawings and the description to refer to the same or like parts.

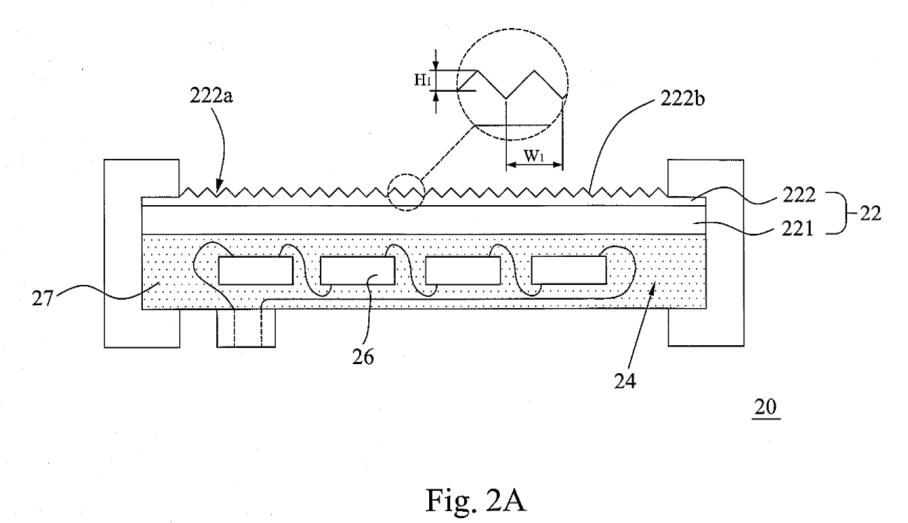

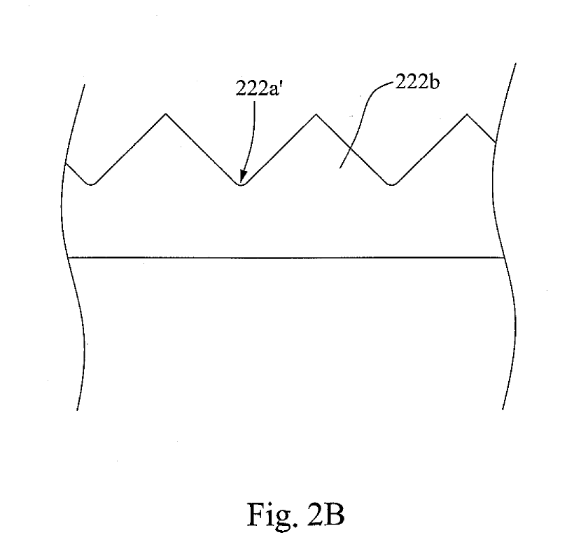

Please refer to FIG. 2A for a solar cell of a first embodiment. The solar cell 20 defines a receiving room 24, which includes an encapsulant material 27 and pluralities of cell units 26. The encapsulant material 27 is ethylene-vinyl acetate copolymer for example and the cell units 26 are singlesilicon solar cells in the present embodiment. However, the cell units 26 can be dye sensitized solar cells, polysilicon solar cells or other apparatus which can transform light energy into electric energy. Moreover, a transparent cover plate 22 is placed over the cell units 26. The transparent cover plate 22 includes a base plate 221 and a structured plate 222. The base plate 221 is made from glass, wherein the thickness thereof is between 3 mm to 12 mm. The structured plate 222 is made from a photo resin, such as a UV-curable resin. However, those skilled in the art can also select other inflexible material as the material of the base plate 221, such as polymethyl methacrylate (PMMA), polycarbonate (PC), polystyrene (PS), polypropene (PP), polyethylene (PE) or polyethylene terephthalate (PET).

Please refer to FIG. 2A again. Pluralities of first patterns 222b are disposed on the incident surface of the structured plate 222. The first patterns 222b are bar-shaped, and the sections thereof are triangular. Because the first patterns 222b are convex bar-shaped and the solar cell 20 is disposed at an angle with horizontal, the water along with the dust can flow down the structured plate 222 from the grooves 222a between the first patterns 222b, which makes the transparent cover plate 22 more easily to clean. In the present embodiment, the height H1 of first patterns 222b is generally half the width W1 of the first patterns 222b. Wherein, the height H1 is 0.025 mm and the width W1 is 0.05 mm, for example. Besides, the grooves 222a′ between the first patterns 222b, as depicted in FIG. 2B, can also be arc-shaped, so as to reduce the accumulation of dust on the grooves 222a′.

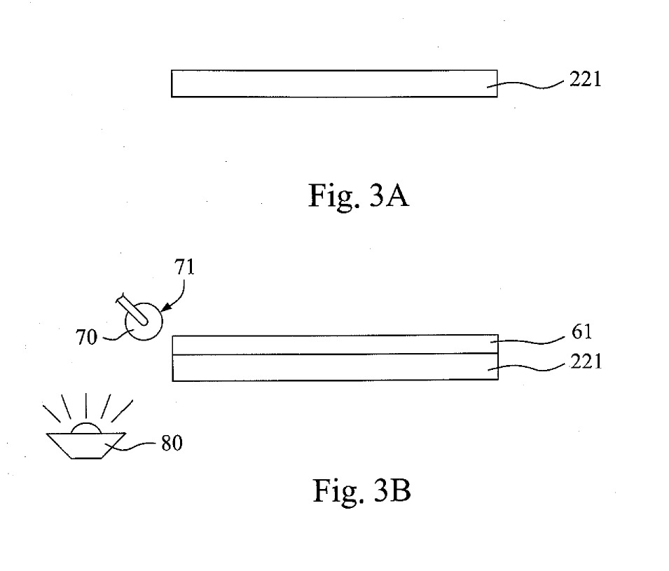

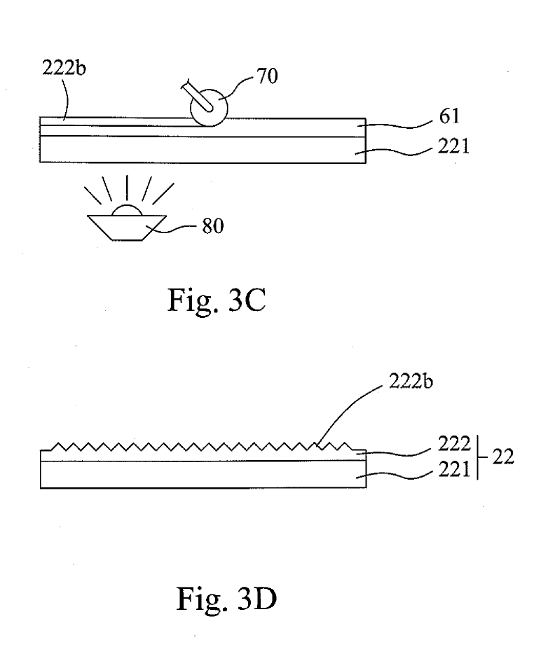

Then, please refer to FIG. 3A to FIG. 3D for a manufacturing process of a transparent cover plate of the first embodiment. First, please refer to FIG. 3A. A base plate 221 is prepared. Then, please refer to FIG. 3B. A photo resin 61 is applied on the base plate 221. Next, the base plate 221 is placed on a transport band (not depicted) to be transported forward, and then the photo resin 61 is over-rolled by a roller 70. The second patterns (not depicted) on a surface 71 of the roller 70 are corresponding to the first patterns 222b depicted in FIG. 2. In the present embodiment, the sections of the first patterns 222b are convex triangular, which means the sections of the second patterns on the roller 70 are concave triangular.

Moreover, there is a UV lamp 80 located under the roller 70. As the roller 70 rolls over the photo resin 61, the UV lamp 80 irradiates the over-rolled photo resin 61 to harden it, forming the first patterns 222b. Then, please refer to FIG. 3D. After the whole photo resin 61 is over-rolled by the roller 70 and irradiated by the UV lamp 80, a structured plate 222 is formed, which means the manufacture of the transparent cover plate 22 is complete. A point for attention, the view of FIG. 3D is perpendicular to the views of FIG. 3B and FIG. 3C. That is to say, FIG. 3B and FIG. 3C are front views, and yet FIG. 3D is a side view.

In the present embodiment, the first patterns 222b are formed on the structured plate 222, which is made from a photo resin. Wherein, the photo resin shrinks slightly during curing. Therefore, the precision of the dimensions of the first patterns 222b is more easily controlled and the transparent cover plate 22 can reach the requirement for the optic effect as well.

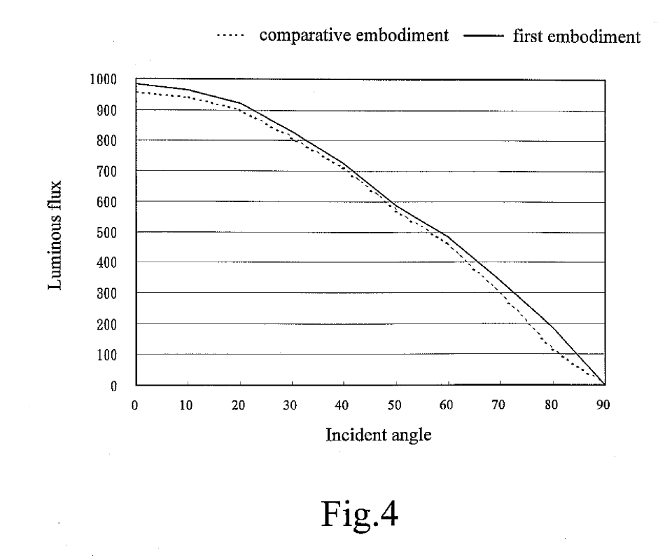

Please refer to FIG. 4 for a comparative drawing, which shows luminous flux of transparent cover plates of the first embodiment and a comparative embodiment when the incident angle of light varies. Moreover, FIG. 4 is a drawing based on the result of a computer optic simulation, wherein the luminous flux of incident light is 1000 lumen and the incident angle of light varies from 0° to 90°. In the comparative embodiment, the transparent cover plate is a pattern glass made by Taiwan Glass Corporation located in Taiwan. Wherein, the patterns of the pattern glass are directly-formed on the glass. As shown in FIG. 4, it is obvious that the transparent cover plate of the first embodiment, comparing to the pattern glass of the comparative embodiment, has higher luminous flux no matter how the incident angle of light varies.

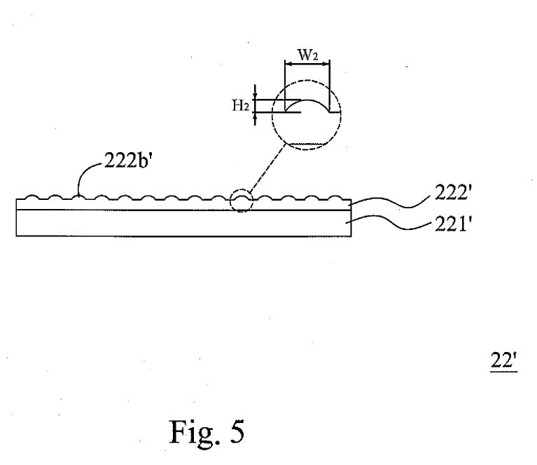

In the first embodiment, the sections of first patterns 222b are triangular. However, those skilled in the art can also vary the section of first patterns 222b into other shape. Please refer to FIG. 5 for a transparent cover plate of the solar cell of the second embodiment. The transparent cover plate 22′ includes a base plate 221′ and a structured plate 222′. The function and formation of the present base plate 221′ are similar to those of base plate 221 of the first embodiment. Wherein, the first patterns 222b′ on the structured plate 222′ are arc-shaped. The height H2 and the width W2 of the first patterns 222b′ can be related by the following formula:

H2/W2=0.05˜0.25

Wherein, the height H2 is 0.03 mm and the width W2 is 0.4 mm, for example.

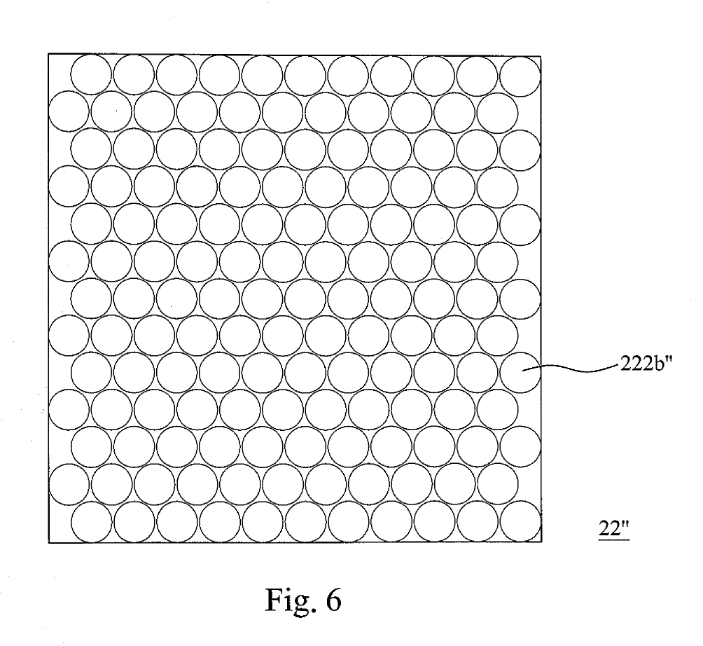

Moreover, those skilled in the art can also vary the first patterns into structures other than bar-shaped structure. Please refer to FIG. 6 for a top view of a transparent cover plate of a solar cell of the third embodiment. The bases of the first patterns 222b″ on the transparent cover plate 222 are circular.

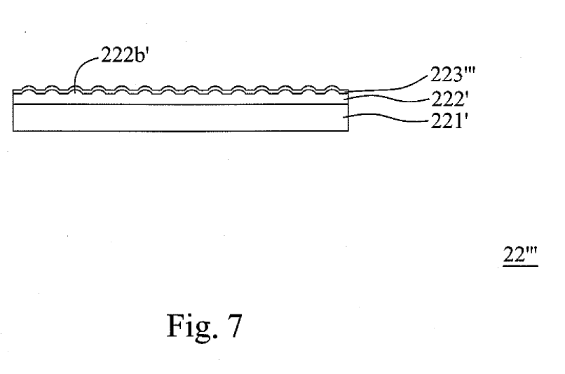

Then, please refer to FIG. 7 for a transparent cover plate of the solar cell of the fourth embodiment. The difference between the present transparent cover plate 22′″ and the transparent cover plate 22″ of the second embodiment is that there is a transparent waterproof material 223′″ applied on the structured plate 222′ of the transparent cover plate 22′″. The waterproof material 223′″ is polytetrafluoro ethylene, for example. In the present embodiment, it is not easy for water to adhere on the transparent cover plate 22′″ due to the waterproof material 223′″.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

I claim:

1. A solar cell, defining a receiving room in where at least a cell unit is located, wherein a transparent cover plate is placed over the cell unit; the solar cell further characterized in that:
the transparent cover plate comprising a base plate and a structured plate which are adhered to each other, wherein the base plate is made from inflexible material, the structured plate is made from a photo resin and pluralities of convex first patterns are disposed on the incident surface of the structured plate.

2. The solar cell according to claim 1, wherein a transparent waterproof material is spread over the incident surface of the structured plate.

3. The solar cell according to claim 2, wherein the waterproof material is polytetrafluoro ethylene.

4. The solar cell according to claim 1, wherein the first patterns are bar-shaped.

5. The solar cell according to claim 4, wherein the sections of the first patterns are triangular.

6. The solar cell according to claim 5, wherein the height of the first patterns is half the width of the first patterns.

7. The solar cell according to claim 4, wherein the sections of the first patterns are arc-shaped.

8. The solar cell according to claim 7, wherein the height and the width of the first patterns can be related by the following formula:
Height/Width=0.05˜0.25

9. The solar cell according to claim 4, wherein there are arc-shaped grooves between the first patterns.

10. The solar cell according to claim 1, wherein the base plate is made from glass.

11. The solar cell according to claim 10, wherein the cell unit is a singlesilicon solar cell and the thickness of the base plate is between 3 mm to 12 mm.

12. The solar cell according to claim 1, wherein the material of the structured plate is selected from the group consisting of polymethyl methacrylate (PMMA), polycarbonate (PC), polystyrene (PS), polypropene (PP), polyethylene (PE) and polyethylene terephthalate (PET).
